(19) United States
(12) Patent Application Publication
(10) Pub. No.: US 2007/0249119 A1
(43) Pub. Date: Oct. 25, 2007

(54) NITRIDE SEMICONDUCTOR DEVICE

(75) Inventor: Wataru Saito, Kanagawa-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/738,116

(22) Filed: Apr. 20, 2007

(30) Foreign Application Priority Data
Apr. 21, 2006 (JP) 2006-118085

(51) Int. Cl. H01L 31/00; H01L 21/8242

(52) U.S. Cl. 438/253; 257/192

(57) ABSTRACT

A nitride semiconductor device includes: a first semiconductor layer; a second semiconductor layer provided on the first semiconductor layer; a p-type region selectively provided in the second semiconductor layer; a gate insulating film provided on the p-type region; a field insulating film provided on the second semiconductor layer surrounding the p-type region; a first and a second main electrodes connected to the second semiconductor layer on opposite sides of the p-type region; and a control electrode provided on the gate insulating film. The first semiconductor layer is made of an undoped nitride semiconductor. The second semiconductor layer is made of an undoped or n-type nitride semiconductor having a wider bandgap than the first semiconductor layer. At least a part of the control electrode extends on the field insulating film.

### CROSS-REFERENCE TO RELATED APPLICATIONS

This application is based upon and claims the benefit of priority from the prior Japanese Patent Application No.2006-118085, filed on Apr. 21, 2006; the entire contents of which are incorporated herein by reference.

### BACKGROUND OF THE INVENTION

1. Field of the Invention

This invention relates to a nitride semiconductor device and more particularly to a nitride semiconductor device having a structure of a heterojunction field effect transistor.

2. Background Art

Nitride semiconductor materials including gallium nitride (GaN) have a wide band gap compared with silicon (Si), thereby, exhibit a high breakdown electric field strength. Therefore, a small and high breakdown voltage device is easy to be realized. That is to say, use of a nitride semiconductor device for a power control device causes a low on-resistance and allows a low loss device to be realized. More particularly, a heterojunction field effect transistor (HFET) using an AlGaN/GaN heterojunction has a simple device structure and is expected to have an excellent high output power control characteristic.

Impurities doping into an AlGaN layer and polarization of an AlGaN/GaN heterostructure produce two-dimensional electron gas (2DEG) in GaN near AlGaN of the AlGaN/GaN heterostructure. Thus, the HFET having the low on-resistance and normally-on characteristic are obtained.

However, it is desirable that the HFET for high output power control has the normally-off characteristic with the aim of preventing a surge current flowing at turn-on to a circuit. In order to meet this requirement, for example, decreasing the 2DEG concentration of HFET causes a shift of a gate threshold voltage to a positive side, thereby the normally-off characteristic is obtained. However, in this case, the on-resistance increases.

In order to obtain the normally-off characteristic while maintaining the low on-resistance, the 2DEG concentration substantially vertically under a gate electrode provided on non-doped or n-type AlGaN needs to be selectively reduced.

This can be realized, for example, by providing a p-type region selectively under the gate electrode. Thus, the gate threshold voltage shifts to increase, and the normally-off characteristic is obtained. However, in this case, in order to reduce the channel resistance in a state of turn-on, a large forward gate bias is needed. However, application of the large forward bias voltage causes a flow problem of a gate leak current. An insulating gate structure is effective to reduce the gate leak current. However, if formation of a gate insulating film and a p-type layer under the gate electrode is processed separately, misalignment occurs, and this misalignment increases the off-set resistances between the gate and the source and between the gate and the drain, and increases the on-resistance.

On the other hand, a semiconductor device having a HFET structure made of a semiconductor including an nitride formed on a substrate, comprising a channel layer, a barrier layer and a gate electrode in this order on the substrate, and having a p-type semiconductor layer between the gate electrode and the channel layer is disclosed (IP 2004-273486A).

### SUMMARY OF THE INVENTION

According to an aspect of the invention, there is provided a nitride semiconductor device including: a first semiconductor layer of an undoped nitride semiconductor; a second semiconductor layer of an undoped or n-type nitride semiconductor having a wider bandgap than the first semiconductor layer, the second semiconductor layer being provided on the first semiconductor layer; a p-type region selectively provided in the second semiconductor layer; a gate insulating film provided on the p-type region; a field insulating film provided on the second semiconductor layer surrounding the p-type region; a first and a second main electrodes connected to the second semiconductor layer on opposite sides of the p-type region; and a control electrode provided on the gate insulating film, at least a part of the control electrode extending on the field insulating film.

According to another aspect of the invention, there is provided a nitride semiconductor device including: a first semiconductor layer of an undoped nitride semiconductor; a second semiconductor layer of an undoped or n-type nitride semiconductor having a wider bandgap than the first semiconductor layer, the second semiconductor layer being provided on the first semiconductor layer; a p-type region selectively provided on the second semiconductor layer; a gate insulating film provided on the p-type region; a field insulating film provided on the second semiconductor layer surrounding the p-type region; a first and a second main electrodes connected to the second semiconductor layer on opposite sides of the p-type region; and a control electrode provided on the gate insulating film, at least a part of the control electrode extending on the field insulating film.

### BRIEF DESCRIPTION OF THE DRAWINGS

FIG. 1 shows the structure of a first example of a nitride semiconductor device according to a present embodiment, where FIG. 1A is a schematic cross section, and FIG. 1B is a schematic plan view.

FIGS. 2A-2F are process cross sections showing a process of manufacturing the nitride semiconductor device of the first example in FIG. 1.

FIG. 3 shows the structure of a second example of the nitride semiconductor device according to the present embodiment, where FIG. 3A is a schematic cross section, and FIG. 3B is a schematic plan view.

FIG. 4 shows the structure of a third example of the nitride semiconductor device according to the present embodiment, where FIG. 4A is a schematic plan view, and FIG. 4B is a schematic cross section along line B-B.

FIG. 5 shows the structure of a fourth example of the nitride semiconductor device according to the present embodiment, where FIG. 5A is a schematic plan view, and FIG. 5B is a schematic cross section along line B-B.

FIG. 6 shows the structure of a fifth example of the nitride semiconductor device according to the present embodiment, where FIG. 6A is a schematic plan view, and FIG. 6B is a schematic cross section along line B-B.

FIG. 7 shows the structure of a sixth example of the nitride semiconductor device according to the present embodiment, where FIG. 7A is a schematic cross section, and FIG. 7B is a schematic plan view.

FIG. 8 shows the structure of a seventh example of the nitride semiconductor device according to the present embodiment, where FIG. 8A is a schematic cross section, and FIG. 8B is a schematic plan view.

FIG. 9 shows the structure of an eighth example of the nitride semiconductor device according to the present embodiment, where FIG. 9A is a schematic cross section, and FIG. 9B is a schematic plan view.

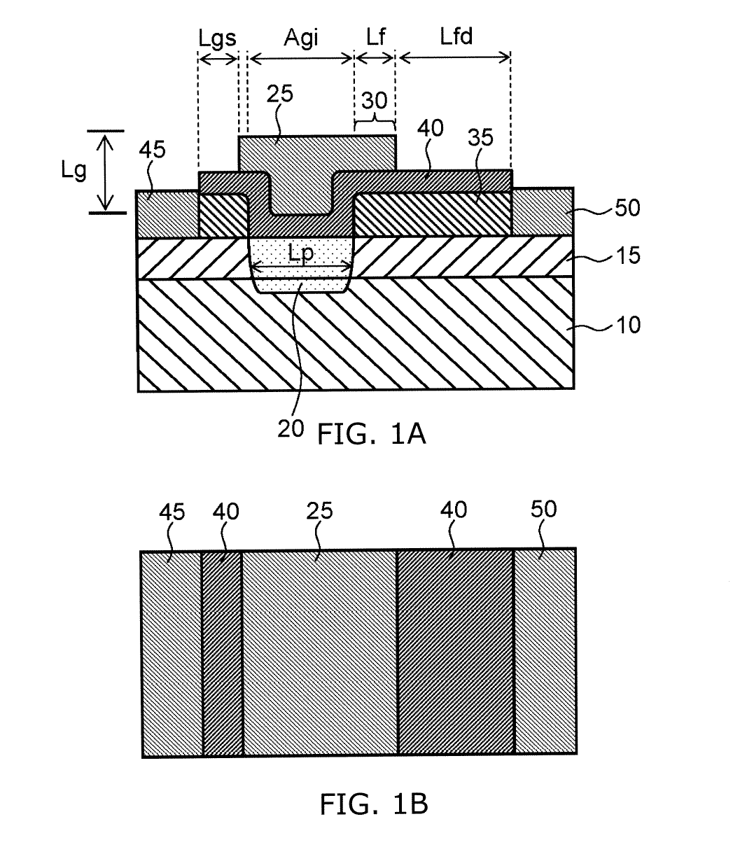

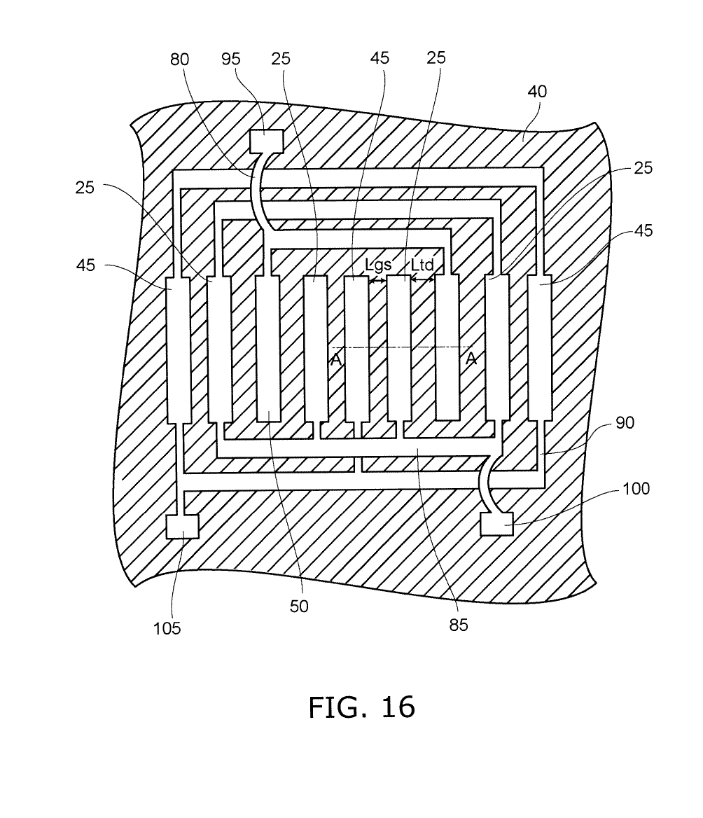

FIGS. 1OA-10E are process cross sections showing a process of manufacturing the nitride semiconductor device of the eighth example in FIG. 9.

FIG. 11 shows the structure of a ninth example of the nitride semiconductor device according to the present embodiment, where FIG. 11A is a schematic cross section, and FIG. 11B is a schematic plan view.

FIGS. 12A-12G are process cross sections showing a process of manufacturing the nitride semiconductor device of the ninth example in FIG. 11.

FIG. 13 shows the structure of a tenth example of the nitride semiconductor device according to the present embodiment, where FIG. 13A is a schematic cross section, and FIG. 13B is a schematic plan view.

FIGS. 14A-14F are process cross sections showing a process of manufacturing the nitride semiconductor device of the tenth example in FIG. 13.

FIG. 15 shows the structure of an eleventh example of the nitride semiconductor device according to the present embodiment, where FIG. 15A is a schematic cross section, and FIG. 15B is a schematic plan view.

FIG. 16 is a schematic plan view of the semiconductor device for which the nitride semiconductor device in the present embodiment can be used.

### DETAILED DESCRIPTION

Embodiments of the invention will now be described with reference to the drawings.

FIG. 1 shows the structure of a first example of a nitride semiconductor device according to a present embodiment, where FIG. 1A is a schematic cross section, and FIG. 1B is a schematic plan view.

In the nitride semiconductor device 5 in the present embodiment, a barrier layer 15 with a band gap broader than a channel layer 10 is provided on a major surface of the channel layer 10. Two-dimensional electron gas (2DEG) is formed in the channel layer 10 near the barrier layer 15. A sheet electron concentration of this 2DEG is, for example, on the order of 1×10¹³ cm⁻². An field insulating film 35 having an opening and a gate insulating film 40 covering the opening provided in the field insulating film 35 are provided in this order on the major surface of the barrier layer 15. The gate insulating film 40 can be formed so as to conform to the field insulating film 35. A gate electrode 25 connected to a field plate electrode 30 is provided on the gate insulating film 40 covering the opening. A p-type region 20 is provided in the barrier layer under the gate electrode 25 and the channel layer 10 near the barrier layer 15. That is to say, the p-type region is provided so as to include 2DEG by passing through the barrier layer 15 selectively and penetrating the channel layer 10. The carrier concentration of the p-type region 20 is preferable to be higher than that of 2DEG in terms of the sheet electron concentration. In addition, the maximum length Lp of the p-type region 20 in the direction substantially parallel to the major surface of the barrier layer is on the same order of an opening diameter Agi provided in the field insulating film 35 (Lp=Agi).

A source electrode 45 and a drain electrode 50 are provided so as to sandwich the field insulating film 35 and the gate insulating film 40 on the barrier layer 15, respectively. These electrodes form each ohmic junction with the barrier layer 15.

Furthermore, there exists a region of the gate electrode 25 extending forward the side of the drain electrode 50, for example, by a distance Lf. This region has the function as the field plate electrode 30. That is to say, the gate electrode 25 and the field plate electrode 30 have the integrated structure.

A distance (Lf+Lfd) between the gate electrode 25 and the drain electrode 50 is longer than a distance Lgs between the gate electrode 25 and the source electrode 45 (Lf+Lfd>Lgs). Such an asymmetric structure allows to maintain the high breakdown voltage and to realize the low on-resistance. Forming integrally the field plate electrode 30 with the gate electrode relaxes the field concentration occurring on the side of the drain electrode 50, thereby allows to improve the breakdown voltage and to suppress current collapse. The longer the distance Lf of the field plate electrode 30, the more the field concentration at the ends of the gate electrode 25 and the p-type region 20 can be suppressed, therefore the distance Lf is preferred to be longer than the distance between the gate electrode 25 and the source electrode 45. Although a distance Lg which the gate electrode 25 is opposed to the p-type region 20 through the gate insulating film 40 decreases less than the opening diameter Agi by a distance of the thickness of the both sideward gate insulating film 40, the opening diameter Agi is on the order of 1-2 micrometers and the gate insulating film thickness is on the order of 5-30 nanometers, therefore the opening diameter Agi equals nearly to the distance Lg and the channel resistance is allowed to be small. Carriers run in the channel layer 10 adjacent to the barrier layer 15. The barrier layer 15 is composed of nitride semiconductor with the band gap broader than the channel layer 10. The gate insulating film 40 has a role in reducing the gate leak current.

The material of the channel layer 10 can illustratively be made of undoped gallium nitride (GaN). The barrier layer 15 can illustratively be made of undoped or n-type aluminum gallium nitride (AlGaN). The field insulating film 35 can illustratively be made of silicon nitride (SiN). The gate insulating film 40 can illustratively be made of SiN and aluminum oxide (Al₂0₃) or the like. Here, the dielectric constant of the gate insulating film 40 is preferable to be higher than the field insulating film.

Furthermore, film thicknesses of each layer can be, for example, 3 micrometers for the channel layer 10, 30 nanometers for the barrier layer 15, 40 nanometers for the p-type region 20, 200 nanometers for the field insulating film 35 and 15 nanometers for the gate insulating film 40.

HFET in the present embodiment has a MIS (Metal-Insulator-Semiconductor) structure that the gate insulating film and the p-type region are formed under the gate electrode. Thus, a depletion layer can be formed by reducing the 2DEG concentration in the p-type region 20. Therefore, it becomes possible to shift the gate threshold value to increase, thus it allows the normally-off characteristic to be obtained. Hence, the surge current flowing at turn-on to the circuit can be prevented. By applying voltage to the gate electrode 25 as required and changing the thickness of the depletion layer occurring at surrounding of the p-type region 20 provided under the gate electrode 25, the current between the source electrode and the drain electrode can be controlled.

Furthermore, by providing the gate insulating film 40, the gate leak current can be reduced. Moreover, the gate electrode 25 is formed so as to cover the p-type region 20 through the gate insulating film 40 and the field insulating film 35. Hence, the increase of the resistance of the off-set portions between the gate and the source and between the gate and the source can be suppressed and the low on-resistance can be achieved.

Next, a method of manufacturing the nitride semiconductor device 5 of the first example will be described.

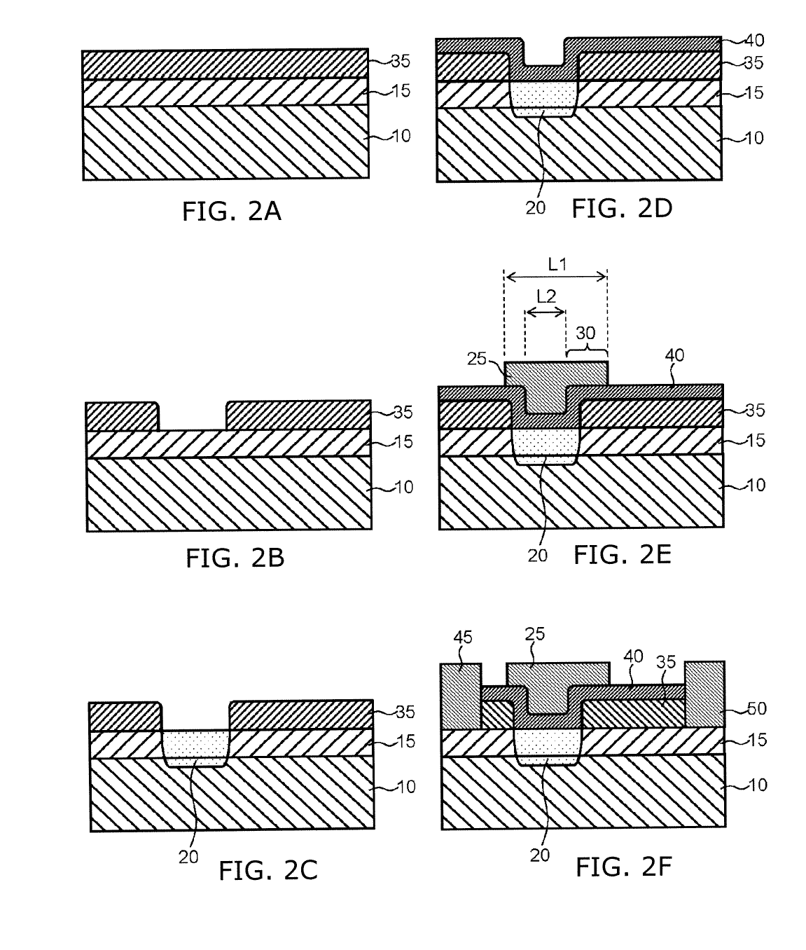

FIGS. 2A-2F are process cross sections showing a process of manufacturing the nitride semiconductor device of the first example in FIG. 1.

With regard to FIG. 2A and the following figures, elements similar to those shown in previous figures are marked with the same reference numerals and not described in detail.

First, as shown in FIG. 2A, the field insulating film 35 is deposited on the barrier layer 15 provided on the channel layer 10. Thereafter, a desired pattern is formed on the field insulating film 35. Then, as shown in FIG. 2B, the field insulating film 35 is opened using etching. Hence, the barrier layer 15 is exposed at the bottom of the opening.

Subsequently, as shown in FIG. 2C, fluorine ions are implanted, for example by ion implantation into the barrier layer 15 at the bottom of the opening, and gases including fluorine are diffused using plasma treatment. With this, the p-type region 20 is formed selectively in the barrier layer 15 at the bottom of the opening and the channel layer 10 near 2DEG.

Furthermore, as shown in FIG. 2D, the gate insulating film 40 is deposited on the field insulating film 35 and the p-type region 20. Thereafter, as shown in FIG. 2E, the gate electrode 25 and the field plate electrode 30 are formed in self alignment on the gate insulating film 40 over the p-type region 20. Then, as shown in FIG. 2F, the source electrode 45 and the drain electrode 50 are formed on the major surface of the barrier layer 15 so as to sandwich the gate electrode 25, respectively. Hence, the nitride semiconductor device 5 of the present example is obtained.

Here, the gate electrode 25 and the field plate electrode 30 have the integrated structure. The field plate electrode 30 is to be the region extending from the gate electrode 25 to the drain electrode 50. That is to say, the length L1 of the gate electrode including the field plate electrode 30 is longer than the opening width L2 (L1>L2).

Moreover, if formation of the p-type region 20 in FIG. 2C and the gate insulating film 40 in FIG. 2D is processed using discrete masks, “misalignment” between the p-type region 20 and the gate electrode 30 is easy to occur. This misalignment causes cases where the off-set resistances between the gate electrode 25 and the source electrode 45 and between the gate electrode 25 and the drain electrode increase, and the on-resistance increases.

On the contrary, the gate electrode 25 (the field plate electrode 30) can be formed reliably on the p-type region 20 by forming in self alignment the gate insulating film 40 and the gate electrode 25 in the opening of the mask (the field insulating film 35) used for forming the p-type region 20, furthermore by lengthening the length L1 of the gate electrode 25 than the gate opening width L2. Therefore, the increase of the off-set resistance can be suppressed.

By the way, in the process shown in FIG. 2C, fluorine (F) is used for the dopant in the p-type region 20. However, the invention is not limited to this, but other dopant, for example, magnesium (Mg), iron (Fe) and manganese (Mn) or the like may be used.

Moreover, as shown in FIG. 2E, after the gate electrode 25 is formed, the source electrode 45 and the drain electrode 50 are formed in FIG. 2F. However, the invention is not limited to this specific example. Alternatively, the gate electrode 25 may be formed after the source electrode 45 and the drain electrode 50 are formed.

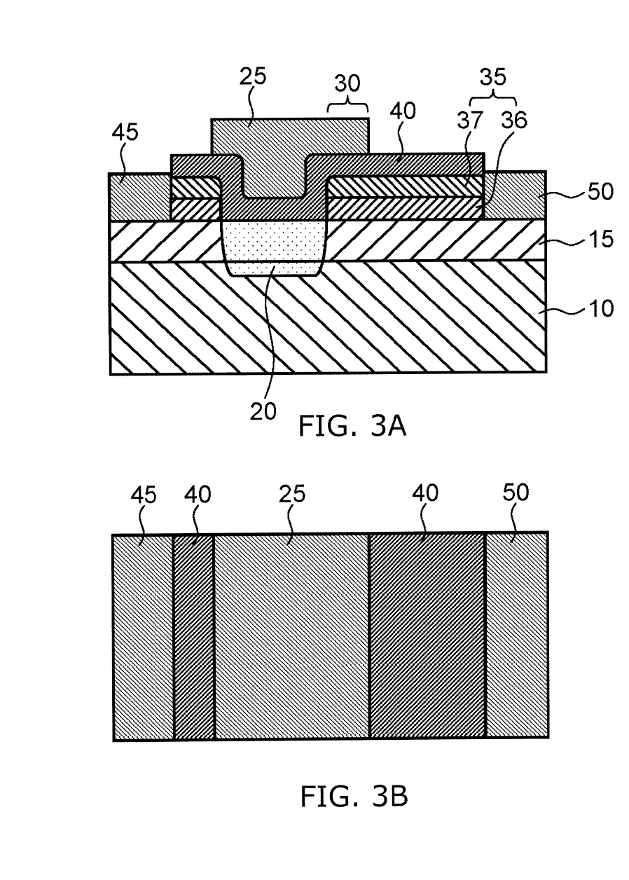

FIG. 3 shows the structure of a second example of a nitride semiconductor device according to the present embodiment, where FIG. 3A is a schematic cross section, and FIG. 3B is a schematic plan view.

The basic structure of the present example is similar to the first example shown in FIG. 1. But the field insulating film 35 has the structure with plural stacked insulating films. That is to say, for example, a first insulating film 36 and a second insulating film 37 are provided in this order as the field insulating film 35 on the barrier layer 15.

The first insulating film 36 can illustratively be made of SiNₓ. The second insulating film 37 can illustratively be made of silicon oxide (SiOₓ) and Al₂O₃. The first insulating film 36 is preferably made of the same material as the gate insulating film 40. But when materials of the first insulating film 36 and the gate insulating film 40 are different, a dielectric constant of the gate insulating film 40 is preferably set to be higher than that of the first insulating film 36.

When a single layer with large thickness is used for the field insulating film 35, there are cases where occurrence of stress causes warps of wafers. On the contrary, in the present example, warps can be suppressed by constituting the field insulating film 35 through stacking plural insulating films. Moreover, as with FIG. 1 previously described, the normally-off characteristic can be achieved while maintaining the low on-resistance.

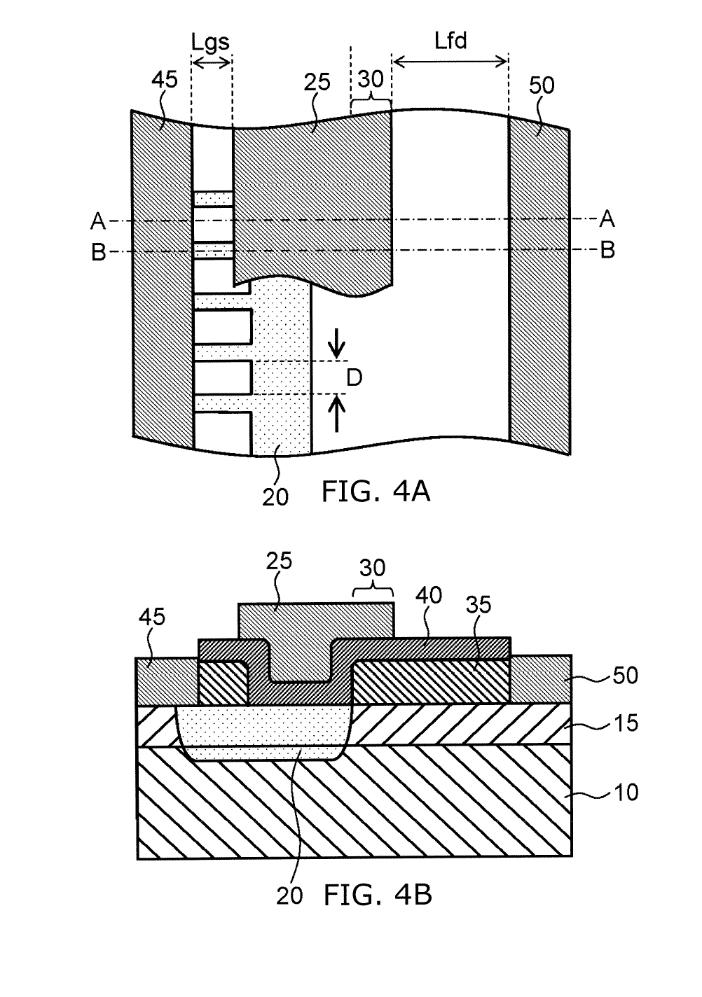

FIG. 4 shows the structure of a third example of the nitride semiconductor device according to the present embodiment, where FIG. 4A is a schematic plan view, and FIG. 4B is a schematic cross section along line B-B.

Here, FIG. 4A is the schematic plan view which a part of the gate electrode 25 is deleted. In addition, a schematic cross section along line A-A of FIG. 4A is similar to the schematic cross section of the nitride semiconductor device 5 in FIG. 1 previously described.

As shown in FIG. 4A, the source electrode 45 and the drain electrode 50 being shaped like a stripe are provided on the major surface of the barrier layer 15, respectively. The source electrode 45 is provided parallel to the drain electrode 50. The gate electrode 25 being shaped like a stripe is provided substantially parallel to the drain electrode 50 between these electrodes 40, 50. Moreover, the p-type region 20 has a stripe part which is parallel to the drain electrode 50 and the gate electrode 25. Furthermore, the p-type region 20 has a plurality of extending parts, each of which extends from the stripe part of the p-type region 20 to the source electrode 45 and is connected to the source electrode 45. These extending parts of the p-type regions 20 are provided at regular interval D.

As shown in FIG. 4B, the p-type region 20 is provided under the gate electrode 25 and between the gate electrode 25 and the source electrode 45.

According to the present example, holes occurring in the p-type region 20 at turn-on can be charged and discharged quickly to the source electrode 45 by connecting the p-type region 20 with the source electrode 45 like this. However, stripes and extended patterns of the p-type region are obtained by designing appropriately the opening pattern formed on the gate insulating film 40. In addition, in the present example, as with FIG. 1 previously described, the normally-off characteristic can also be achieved while maintaining the low on-resistance.

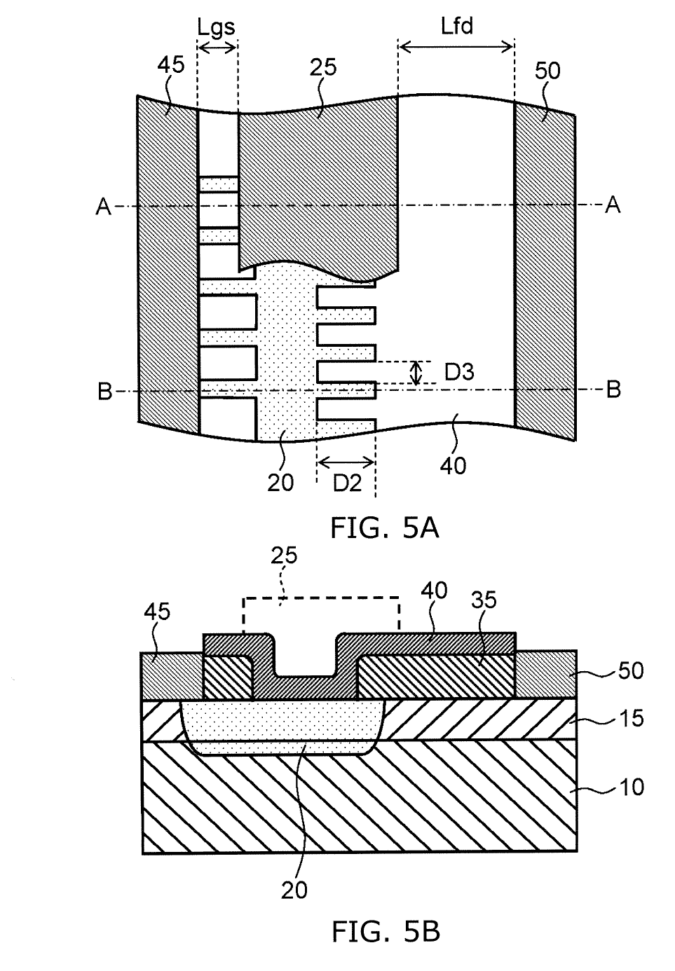

FIG. 5 shows the structure of a fourth example of the nitride semiconductor device according to the present embodiment, where FIG. 5A is a schematic plan view, and FIG. 5B is a schematic cross section along line B-B.

Here, FIG. 5 is the schematic plan view which a part of the gate electrode 25 is deleted. In addition, a schematic cross section along line A-A of FIG. 5A is similar to the schematic cross section of the nitride semiconductor device 5 in FIG. 1 previously described.

The basic structure of the present example is similar to FIG. 4 described previously. However, plural extended p-type regions 20 are also structurally extended toward the drain electrode 50 located perpendicularly to the p-type region 20 provided under the gate electrode 25.

Furthermore, as shown in FIG. 5B, the p-type region 20 is provided between the source electrode 45 and substantially center of the source electrode 45 and the drain electrode 50. Moreover, the p-type region 20 is provided from the channel layer 10 to the field insulating film 35.

In this way, also extending the p-type region 20 toward the drain direction suppresses a short channel effect and allows a channel leak during application of high voltage to be suppressed. Hence, the effective channel length shortens, thus the low on-resistance is obtained due to decrease of the channel resistance.

The distance of the p-type region 20 extended toward the drain electrode is assumed to be D2. The p-type region 20 extended toward the drain electrode is evenly provided in a parallel direction to the source electrode 45, and the distance between the p-type regions 20 is assumed to be D3. When the distance D2 is larger than the distance D3 (D2>D3), a screening effect is obtained by the p-type region 20. Also in the present example, as with FIG. 1 previously described, the normally-off characteristic can be achieved while maintaining the low on-resistance.

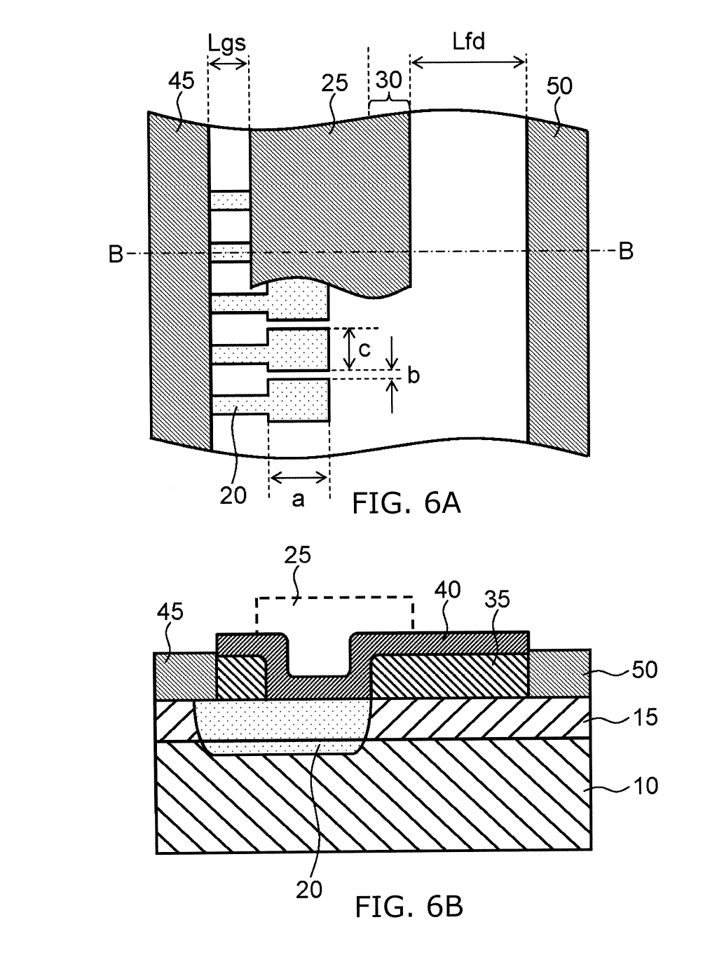

FIG. 6 shows the structure of a fifth example of the nitride semiconductor device according to the present embodiment, where FIG. 6A is a schematic plan view, and FIG. 6B is a schematic cross section along line B-B. Here, FIG. 6A is the schematic plan view which a part of the gate electrode 25 is deleted. In addition, a schematic cross section along line A-A of FIG. 6A is similar to the schematic cross section of the nitride semiconductor device 5 in FIG. 1A previously described. Furthermore, a schematic cross section along line B-B of FIG. 6B is similar to the schematic cross section of the nitride semiconductor device 5 in FIG. 4B previously described.

The basic structure of the present example is similar to FIG. 4 described previously. However, the p-type region 20 substantially parallel to the source electrode 45 has a structure evenly separated. Here, the spacing between the separated p-type region 20 is assumed to be b. Moreover, the separated p-type region 20 has the length c in the substantially parallel direction to the source electrode 45, and the length a in the substantially vertical direction to the source electrode 45. The relationship among them is that the length a is the longest, and the spacing b and the length c become smaller in this order (a>c>b).

According to the present example, the channel leak current can be suppressed by setting the length a to be larger than the spacing b specifically (a>b). This is due to suppression of the decrease of the potential barrier in the depletion layer extending from the p-type region by the drain voltage. Thus, the normally-off characteristic can be achieved while maintaining the low on-resistance.

In addition, when the carrier concentration of the p-type region 20 is increased higher than, for example, about 1×10¹³ cm⁻² in terms of the sheet carrier concentration (P⁺-type region), the spacing b of the adjacent p-type region 20 enables to control the gate threshold voltage. With this, even if the concentration of the p-type region is not exactly controlled, the normally-off characteristic can be achieved while maintaining the low on-resistance.

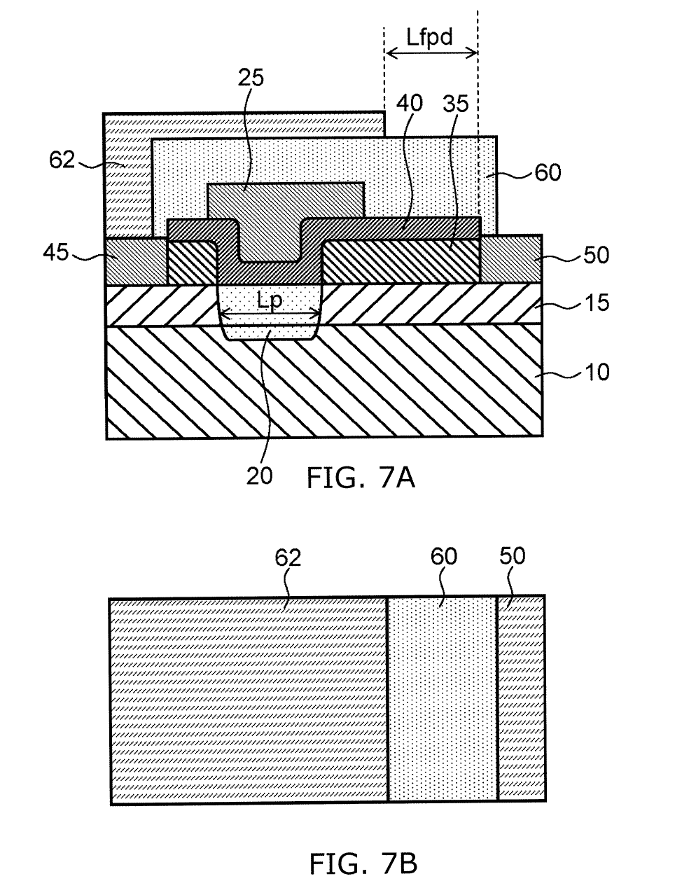

FIG. 7 shows the structure of a sixth example of the nitride semiconductor device according to the present embodiment, where FIG. 7A is a schematic cross section, and FIG. 7B is a schematic plan view.

The basic structure of the present example is similar to FIG. 1 described previously. However, a second field insulating film 60 is provided on the major surfaces of the gate electrode 25, the gate insulating film 40 and the source electrode 45 as well as the drain electrode on the side of the gate electrode 25. A second field plate electrode 62 connected to the source electrode 45 is structurally provided on this second field insulating film 60.

Here, the shortest distance between the second field plate electrode 62 and the drain electrode 50 is assumed to be Lfpd. The distance between the field plate electrode 30 and the drain electrode is assumed to be Lfd.

In this way, by decreasing the shortest distance Lfpd between the second plate electrode 62 and the drain electrode 50 less than the distance Lfd between the field plate electrode 30 and the drain electrode 50 (Lfd>Lfpd), the electric field concentration occurring at the end portion of the field plate electrode 30 on the side of the drain electrode 50 can be relaxed. Thus, the high breakdown voltage can be increased. Moreover, as with FIG. 1 previously described, the normally-off characteristic can be achieved while maintaining the low on-resistance.

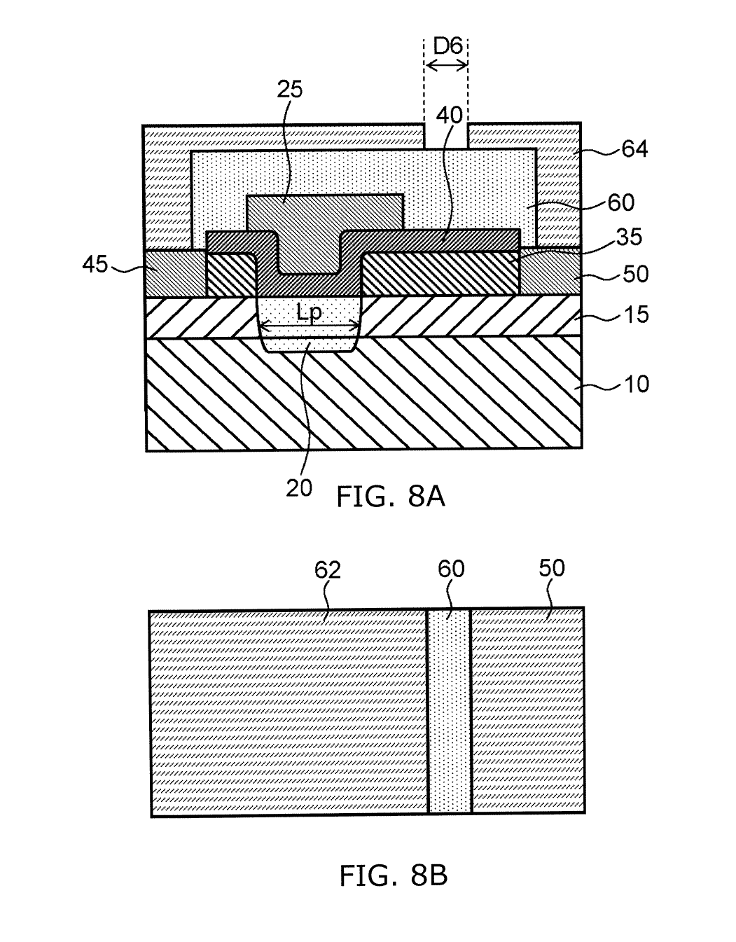

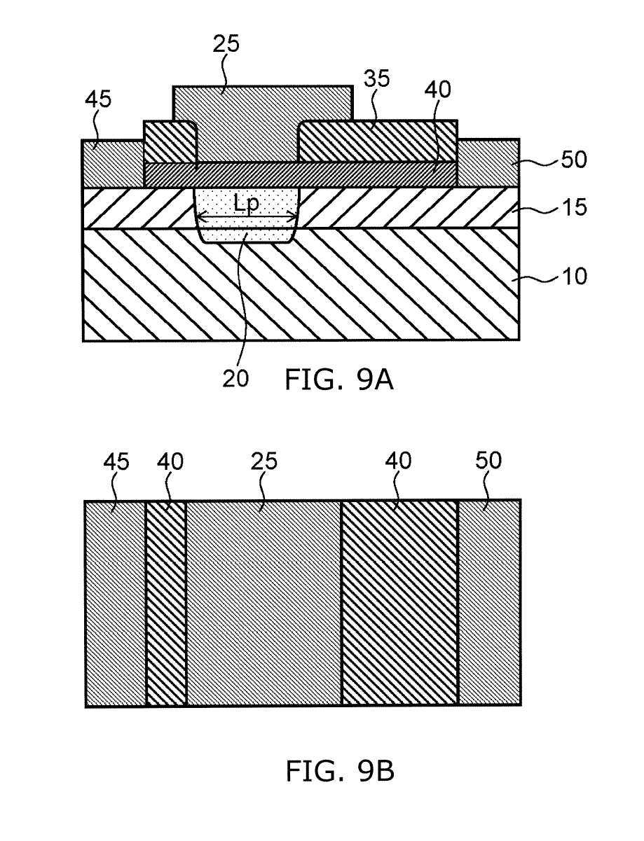

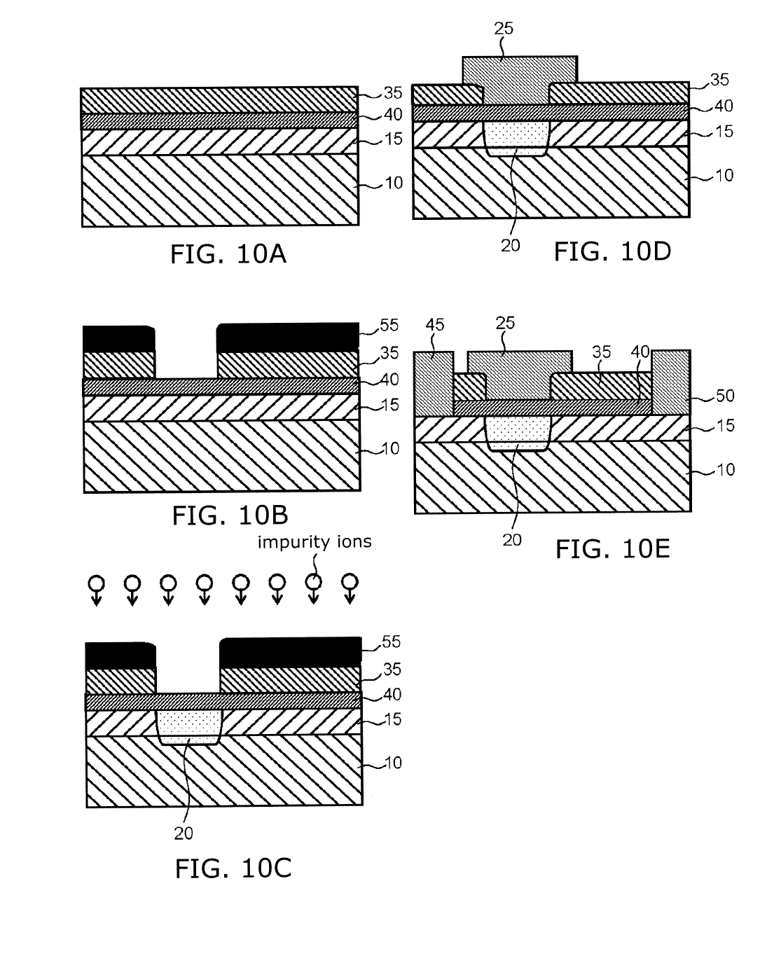

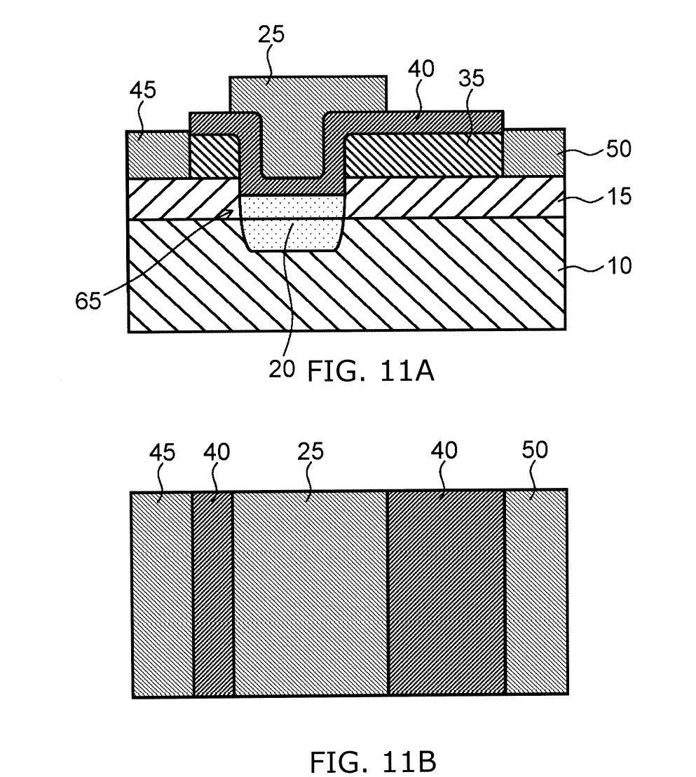

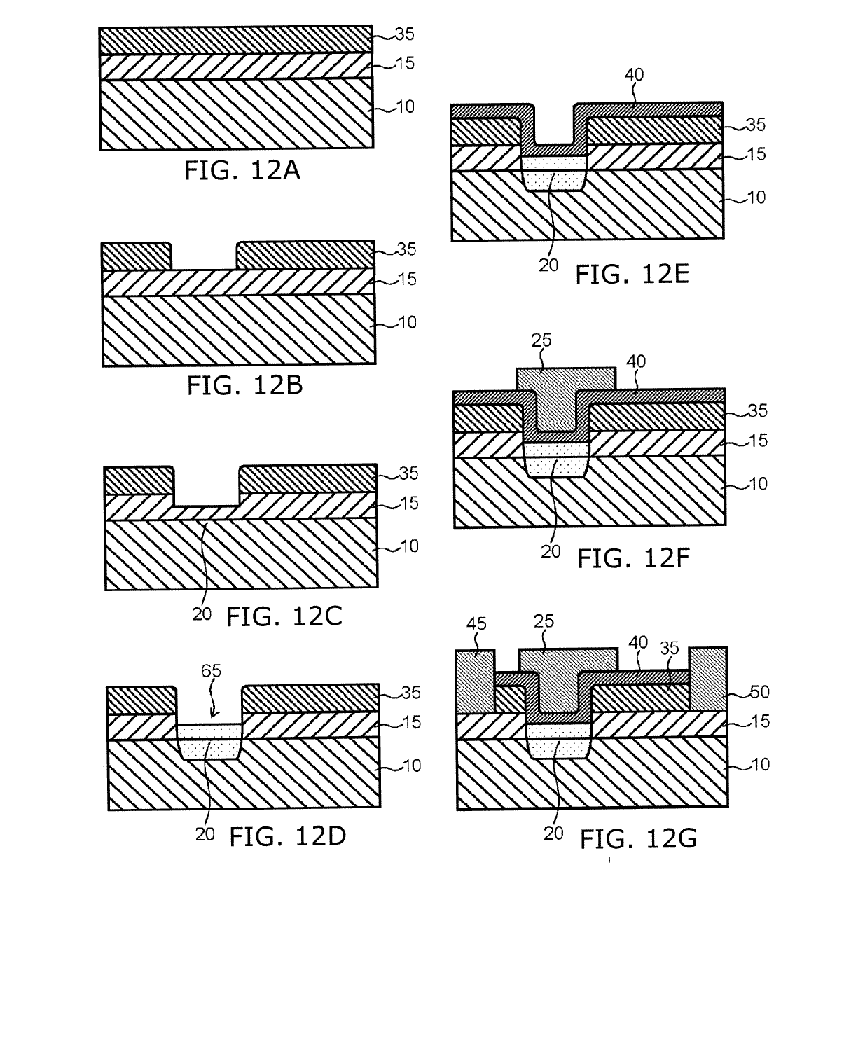

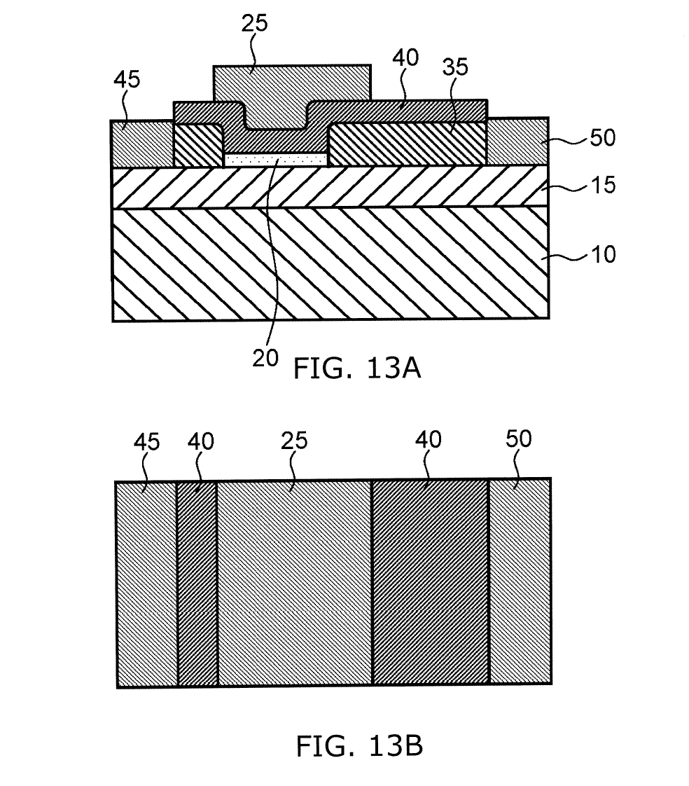

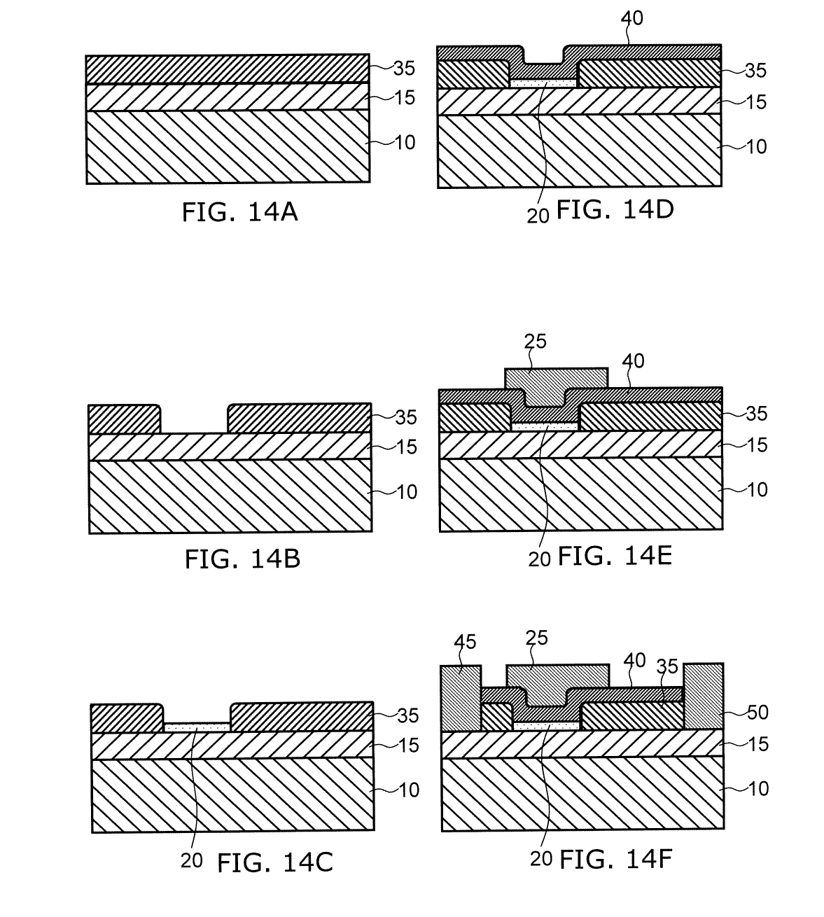

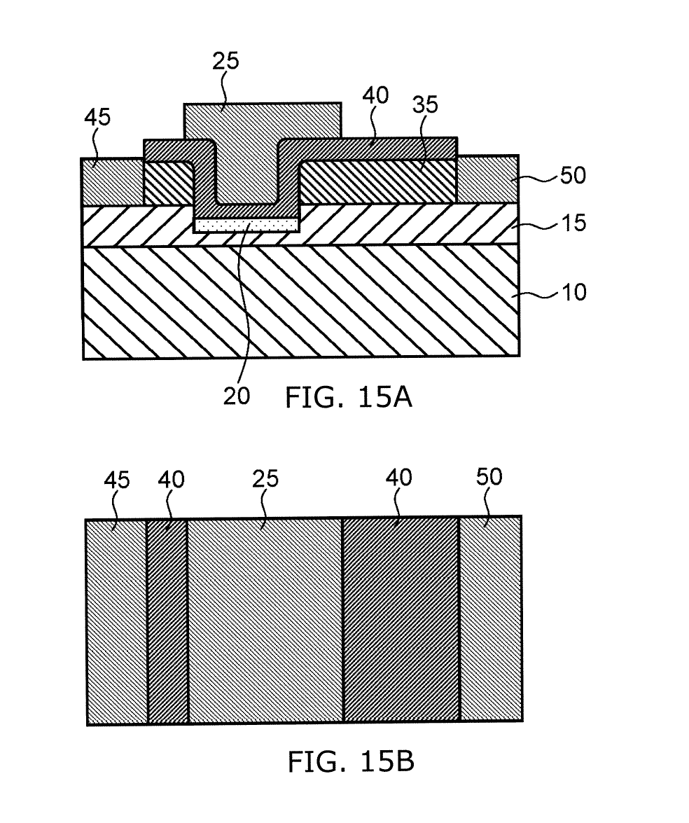

FIG. 8 shows the structure of a seventh example of the nitride semiconductor device according to the present embodiment, where FIG. 8A is a schematic cross section, and FIG. 8B is a schematic plan view.

The basic structure of the present example is similar to FIG. 7 described previously. However, a third field plate electrode 64 connected to the drain electrode 50 is structurally provided on the second field insulating film. Here, the second field plate electrode 62 and the third field plate electrode 64 are provided with the separation distance D6.

In this way, by providing the third field plate electrode 64, the electric field concentration occurring at the end portion of the drain electrode 50 on the side of the gate electrode 25 can be further relaxed. Thus, the high breakdown voltage can be increased. Also in the present example, as with FIG. 1 previously described, the normally-off characteristic can be achieved while maintaining the low on-resistance.

FIG. 9 shows the structure of an eighth example of the nitride semiconductor device according to the present embodiment, where FIG. 9A is a schematic cross section, and FIG. 9B is a schematic plan view.

FIGS. 10A-10E are process cross sections showing a process of manufacturing the nitride semiconductor device of the eighth example in FIG. 9.

As shown in FIG. 9A, the basic structure of the present example is similar to FIG. 1 described previously. However, the gate insulating film 40 is provided on the barrier layer 15 and the p-type region 20. The field insulating film 35, the gate electrode 25 and the field plate electrode 30 are provided on the gate insulating film 40 in this order. Here, the p-type region 20 is structurally provided under the gate electrode through the gate insulating film 40.

Also in the present example, as the gate electrode 25 has the MIS structure, the normally-off characteristic can be achieved while maintaining the low on-resistance.

Such a structure can be formed by the process of manufacturing shown in FIG. 10. That is to say, as shown in FIG. 10, the barrier layer 15 is provided on the channel layer 10. The gate insulating film 40 and the field insulating film 35 are deposited on the barrier layer 15 in this order using CVD (Chemical Vapor Deposition) method or sputtering method. Thereafter, the desired pattern is formed on the field insulating film 35 using a resist mask 55.

In addition, as shown in FIG. 10B, the field insulating film 35 is opened by etching. At this time, the gate insulating film 40 has a role as an etching stopping layer. Therefore, the etching rate of the field insulating film 35 is preferable to be higher than that of the gate insulating film 40, Subsequently as shown in FIG. 10C, impurity ions are implanted using, for example, an ion implantation method from above the resist mask. Here, the resist mask and the field insulating film 35 have a role to block fluorine ions from being implanted. Then, the p-type region 20 is formed in the channel layer 10 near the barrier layer 15 and 2DEG through the gate insulating film at the bottom of the opening.

And then, after removal of the resist mask, as shown in FIG. 10D, the gate electrode 25 is formed around the opened field insulating film 35.

Thereafter, as shown in FIG. 10E, the source electrode 45 and the drain electrode 50 are provided on the major surface of the barrier layer 15 so as to sandwich the gate electrode 25, respectively. Thus, the nitride semiconductor device 5 of the present example shown in FIG. 9 is obtained.

Furthermore, according to the present example, by providing the gate insulating film 40 between the field insulating film 35 and the barrier layer 15, the damage of the barrier layer 15 by etching can be prevented. By the way, when the gate insulating film 40 damaged by the ion implantation method is removed, for example, by etching and the gate insulating film 40 is deposited again, the first insulating film 36 is to be the gate insulating film 40 and the second insulating film 37 is to be the field insulating film 35, in FIG. 3 described previously. Also in the present example, the similar effect to FIG. 1 is achieved.

FIG. 11 shows the structure of a ninth example of the nitride semiconductor device according to the present embodiment, where FIG. 11A is a schematic cross section, and FIG. 11B is a schematic plan view.

FIGS. 12A-12G are process cross sections showing a process of manufacturing the nitride semiconductor device of the ninth example in FIG. 11.

As shown in FIG. 11A, the basic structure of the present example is similar to FIG. 1 described previously. However, a recess portion 65 is provided under the gate electrode 25. That is to say, the thickness of the p-type region 20 provided in the barrier layer 15 is partially small in the structure. Here, the film thickness of the barrier layer 15 without providing the recess portion 65 is, for example, about 30 nanometers.

In this way, by providing the recess and decreasing the film thickness of the p-type region 20, the gate threshold voltage can be further shifted to increase. That is, the normally-off characteristic can be achieved while maintaining the low on-resistance.

Here, even if the p-type region 20 is not formed, the normally-off characteristic should be achieved, if the barrier layer with the thickness, for example, about 5 nanometers could be formed by the recess 65. But in reality, formation of the film like this is extremely difficult.

On the contrary, according to the present example, by providing the p-type region 20 while providing the recess portion 65 under the gate electrode 25, the thickness between the gate insulating film 40 and the channel layer 10 can be 5 nanometers or more. Thus, the gate threshold voltage can be further largely shifted to increase, and the normally-off characteristic can be achieved while maintaining the low on-resistance.

The structure of the present example can be manufactured using the manufacturing process shown in FIG. 12. That is to say, the manufacturing process available for the present example is the approximately similar process to FIG. 2. However, as shown in FIG. 12C, the recess 65 is formed in the barrier layer 15 exposed to the bottom of the opening, for example, by dry etching. Here, the film thickness of the barrier layer 15 at the bottom of the recess 65, for example, may be more than 5 nanometers.

Thereafter, as shown in FIG. 12D, fluorine ions are implanted using the ion implantation method and gases including fluorine is diffused using plasma treatment. Thus, the p-type region 20 is formed selectively in the barrier layer 15 at the bottom of the opening and the channel layer 10 near 2DEG.

Then, as shown in FIG. 12E, the gate insulating film 40 is deposited on the field insulating film 35 and the p-type region 20 using the CVD method and the sputtering method. Thereafter, as shown in FIG. 12F, the gate electrode 25 and the field plate electrode 30 are formed on the gate insulating film 40 over the p-type region 20 using deposition and lift-off.

As shown in FIG. 12G, the source electrode 45 and the drain electrode 50 are formed on the major surface of the barrier layer 15 so as to sandwich the gate electrode 25, for example, using the CVD method and the sputtering method, respectively. Thus, the nitride semiconductor device 5 of the present example is obtained. Moreover, an etching depth of the recess 65 may be nearly equal to the film thickness of the gate insulating film 40, but is not limited to this.

FIG. 13 shows the structure of a tenth example of the nitride semiconductor device according to the present embodiment, where FIG. 13A is a schematic cross section, and FIG. 13B is a schematic plan view.

FIGS. 14A-14F are process cross sections showing a process of manufacturing the nitride semiconductor device of the tenth example in FIG. 13.

As shown in FIG. 13A, the basic structure of the present example is similar to FIG. 1 described previously. However, in the present example, the p-type region 20 comprised of, for example, gallium nitride (GaN) is selectively grown between the gate insulating film 40 under the gate electrode 25 and the barrier layer 15. This p-type region 20 can be formed in self-alignment as described later. If the barrier layer 15 is formed to be in the n-type, the depletion layer is extended by a built-in potential of the pn junction formed between the barrier layer 15 and the p-type region 20 even though the gate bias voltage is zero, and the 2DEG region of the channel layer 10 just under it can be depleted. That is to say, even if the epitaxially grown p-type region is used like this, as with the example previously described, the normally-off characteristic can be achieved while maintaining the low on-resistance.

The structure of the present example can be formed using the manufacturing process shown in FIG. 14. That is, the manufacturing process available for the present example, is approximately similar to the process in FIG. 2. However, as shown in FIG. 14C, the p-type region 20 comprised of, for example, GaN is epitaxially grown selectively in the barrier layer 15 exposed to the bottom of the opening.

Thereafter, as shown in FIG. 14D, the gate insulating film 40 is deposited on the field insulating film 35 and the p-type region 20.

Then, as shown in FIG. 14E, the gate electrode 25 and the field plate electrode 30 are formed on the gate insulating film 40 over the p-type region 20.

As shown in FIG. 14G, the source electrode 45 and the drain electrode 50 are formed respectively on the major surface of the barrier layer 15 so as to sandwich the gate electrode 25. Also in the present example, the similar effect to FIG. 1 previously described is achieved.

Here, GaN is used for material of the p-type region in the present example, however the present invention is not limited to this. Indium gallium nitride (InGaN) may be used in order to increase the p-type dopant concentration. Moreover, the p-type region 20 is epitaxially grown selectively in the present example, but the present example is not limited to this.

For example, as shown in FIG. 15, the p-type region 20 comprised of, for example, GaN may be selectively epitaxially grown on the bottom of the recess portion 65 selectively formed in the barrier layer 15. The effect similar to the present embodiment can be achieved also in this way.

The embodiment of the invention has been described with reference to the examples. However, the invention is not limited to these examples. Any other modification examples which a person skilled in the art can easily arrived at can be applied.

For instance, as shown in FIG. 16, a semiconductor device called, for example, “multifinger-type” can be formed by arranging in parallel plural nitride semiconductor devices 5 in the present embodiment and interconnecting them.

FIG. 16 is a schematic plan view of the semiconductor device for which the nitride semiconductor device in the present embodiment can be used.

Here, the schematic cross section along A-A line is similar to the schematic cross section of FIG. 1A previously described.

In this device, as has been described, the plural source electrodes 45, the gate electrodes 25 and the drain electrodes 50 are provided respectively in parallel on the gate insulating film 40. These electrodes are in a striped configuration. For instance, the gate electrodes 25 are provided respectively so as to sandwich the source electrodes 45, for example, along the substantially perpendicular direction to the long axis direction of the source electrodes 45. The drain electrodes 50, the gate electrodes 25 and the source electrodes 45 are provided respectively in this order in parallel along the opposite direction to the source electrodes 45 across the gate electrodes 25.

Then, for instance, drain connection lines 80 are connected to the ends of the drain electrodes 50 in the longitudinal direction. The gate electrodes 25 and the source electrodes 45 are similarly connected to gate interconnection lines 85 and source interconnection lines 90, respectively. These interconnection lines are discriminated every electrode. Here, adjacent nitride semiconductor devices share common interconnection lines of the same electrodes. And then, each electrode is structurally connected to each connection portion, for example, a drain connection portion 95, a gate connection portion 100 and a source connection portion 105 through each interconnection line.

In this way, by arranging in parallel plural nitride semiconductor devices in the present embodiment and interconnecting them, a semiconductor device 70 which can increase a current capacity and treat a large power signal is obtained.

Moreover, in the present example, a supporting substrate is not shown in a figure, but the present example is not limited to the supporting substrate material. For example, the invention can be based on materials of sapphire, silicon carbide (SiC), Si or GaN for the supporting substrate.

Furthermore, in the present embodiment, a combination of AlGaN/GaN is explained, but similar effects are achieved by combinations of nitride semiconductors such as GaN/InGaN, aluminum nitride (AIN)/AlGaN or boron aluminum nitride (BAlN)/GaN.

The present embodiment using the undoped AlGaN barrier layer for the barrier layer is explained, but can be based on using the n-type AlGaN layer. Furthermore, the invention can be based on a formation of a cap layer comprised of, for example, the undoped AlGaN or the n-type GaN on the barrier layer.

In addition, each element included in each example described above can be combined to the extent possible, and these combinations are also encompassed within the scope of the invention as long as they include the features of the invention.

By the way, the “nitride semiconductor” used herein includes semiconductors having any composition represented by the chemical formula BₓAl_{y}Ga_{z}In_{1-x-y-z}N (0≦x≦1, 0≦y≦1, 0≦z≦1, x+y+z≦1) where the composition ratios x, y, and z are varied in the respective ranges. Furthermore, the “nitride semiconductor” also includes those further containing any of various impurities added for controlling conductivity types.

1. A nitride semiconductor device comprising:
a first semiconductor layer of an undoped nitride semiconductor;
a second semiconductor layer of an undoped or n-type nitride semiconductor having a wider bandgap than the first semiconductor layer, the second semiconductor layer being provided on the first semiconductor layer;
a p-type region selectively provided in the second semiconductor layer;
a gate insulating film provided on the p-type region;
a field insulating film provided on the second semiconductor layer surrounding the p-type region;
a first and a second main electrodes connected to the second semiconductor layer on opposite sides of the p-type region; and
a control electrode provided on the gate insulating film, at least a part of the control electrode extending on the field insulating film.

2. The nitride semiconductor device according to claim 1, wherein the p-type region penetrates the second semiconductor layer and intrudes into the first semiconductor layer.

3. The nitride semiconductor device according to claim 1, wherein the gate insulating film extends on the field insulating film.

4. The nitride semiconductor device according to claim 1, wherein the gate insulating film extends between the second semiconductor layer and the field insulating film.

5. The nitride semiconductor device according to claim 1, wherein the field insulating film is made of a plurality of insulating films stacked each other.

6. The nitride semiconductor device according to claim 1, wherein the p-type region is connected to the first main electrode.

7. The nitride semiconductor device according to claim 1, wherein
the first main electrode and the control electrode are formed in parallel stripes, and
the p-type region has a stripe part extending in parallel to the control electrode, and a plurality of extending parts extending from the stripe part toward the first main electrode and connected to the first main electrode.

8. The nitride semiconductor device according to claim 7, wherein the p-type region further has a plurality of extending parts extending from the stripe part toward the second main electrode.

9. The nitride semiconductor device according to claim 1, wherein
the control electrode is formed a stripe extending along a first direction, and
the p-type region has a plurality of divided parts separated each other along the first direction.

10. The nitride semiconductor device according to claim 9, wherein a length of each of the divided parts along the first direction is greater than a spacing between the divided parts.

11. The nitride semiconductor device according to claim 10, wherein a carrier concentration of the p-type region is higher than a concentration of a two-dimensional electron gas formed in the first semiconductor layer near the second semiconductor layer in terms of a sheet carrier concentration.

12. The nitride semiconductor device according to claim 1, wherein the gate insulating film conforms to the field insulating film.

13. The nitride semiconductor device according to claim 1, wherein the p-type region includes fluorine as a major dopant.

14. The nitride semiconductor device according to claim 1, further comprising:
a second field insulating film provided on the control electrode; and
a second field pate electrode provided on the second field insulating film and connected to the first main electrode.

15. The nitride semiconductor device according to claim 14, further comprising a third field pate electrode provided on the second field insulating film and connected to the second main electrode.

16. The nitride semiconductor device according to claim 1, wherein the p-type region is recessed from a surface of the second semiconductor layer.

17. A nitride semiconductor device comprising:
a first semiconductor layer of an undoped nitride semiconductor;
a second semiconductor layer of an undoped or n-type nitride semiconductor having a wider bandgap than the first semiconductor layer, the second semiconductor layer being provided on the first semiconductor layer;
a p-type region selectively provided on the second semiconductor layer;
a gate insulating film provided on the p-type region;
a field insulating film provided on the second semiconductor layer surrounding the p-type region;
a first and a second main electrodes connected to the second semiconductor layer on opposite sides of the p-type region; and
a control electrode provided on the gate insulating film, at least a part of the control electrode extending on the field insulating film.

18. The nitride semiconductor device according to claim 17, wherein the p-type region is made of a nitride semiconductor having a narrower bandgap than the second semiconductor layer.

19. The nitride semiconductor device according to claim 17, wherein the gate insulating film extends on the field insulating film.

20. The nitride semiconductor device according to claim 17, wherein the p-type region is provided on a bottom of a recess which is formed in the second semiconductor layer.
